(19) United States
(12) Patent Application Publication
(10) Pub. No.: US 2016/0155651 A1
(43) Pub. Date: Jun. 2, 2016

(54) METHOD OF FORMING WAFERLESS INTERPOSER

(71) Applicant: Advance Process Integrate Technology, Ltd., Hukou Township (TW)

(72) Inventors: Wen-Hao HSIEH, Hukou Township (TW); Chih-Hsiung LEE, Hukou Township (TW); Tien-Hsiang CHANG, Hukou Township (TW)

(21) Appl. No.: 14/953,236

(22) Filed: Nov. 27, 2015

(30) Foreign Application Priority Data
Nov. 27, 2014 (TW) 103141292
Nov. 9, 2015 (TW) 104136774

(51) Int. Cl. H01L 21/48; H01L 21/683

(52) U.S. Cl. CPC H01L 21/4857; H01L 21/486; H01L 21/6835; H01L 2221/68345; H01L 2221/68359; H01L 2221/68381

(57) ABSTRACT

A method for forming a waferless interposer comprises the following steps. A transparent carrier is provided. A buffer layer is formed on the transparent carrier. First pads are formed on the buffer layer, and interconnections are formed on the first pads. A non-conductive layer is formed on the buffer layer and filled between adjacent the interconnections, wherein the upper surfaces of the interconnections are exposed on the non-conductive layer. A first redistribution procedure is performed to form a first conductive pattern on the non-conductive layer for connecting with the interconnections. A passivation layer is formed on the first conductive pattern, and is defined to form first contact holes thereon. Second pads are formed on the passivation layer to connect with the first conductive pattern through the first contact holes. After, a laser below the transparent carrier irradiates laser beam on the buffer layer to dissociate it for separating the interposer from the transparent carrier.

This application claims the benefit of Taiwan Patent applications Serial No. 103141292, filed Nov. 27, 2015.

### FIELD OF THE INVENTION

The present invention relates to a method of forming an interposer, and more particularly to a method of forming the interposer without using a wafer substrate.

### BACKGROUND OF THE INVENTION

With the size of circuit patterns shrinking to tens of nanometer, the fabricated chips integrate more computing functions and more transistor devices. Thereby, the number of I/O pins of a chip increases largely and the traditional packaging process encounters the very critical challenges.

For instance, it is difficult to apply the existing wire bonding techniques to bond wires in a chip package because the number of leading wires increases largely. Multiple wire interconnections also cause resistance increasing considerably, therefore the chip package has severe heat dissipation problems. Besides, the flip chip technique in prior art can only be applied to single layer chip package and is hard to be applied to the chip package with a large number of pins.

Therefore, the interposer is widely used to serve as the connecting bridge between the chips and the print circuit boards in rapidly developed 2.5D and 3D packaging techniques. The common manufacturing process of the interposer includes the steps of thinning and drilling the wafer substrate, and filling conductive materials thereon. For reducing the thickness of the wafer substrate from 600-700 microns to 25-200 microns, the chemical mechanic polishing (CMP) procedure is applied to polish the backside of the wafer substrate. Because it needs to remove a considerable amount of wafer material from the substrate, the CMP procedure usually spends a lot of time. Besides, after the CMP procedure, the wafer substrate usually has uneven thickness and damaged edges, thereby to reduce the product yield rate.

On the other hand, because the polished wafer substrate is very thin, it is difficult to process on it and the probability of wafer breakage is increasing. For solving that problem, the temporary bonding technique is applied to attach the thin wafer substrate on a carrier by adhesives or electrostatic adhesion for processing. By using the carrier, the wafer to substrate gets enough support in the processing. However, when the wafer substrate is very thin, it is still possible for the wafer substrate to be cracked in the process. Besides, because the temperature tolerance of the adhesive is about 200 degrees Celsius, the wafer substrate can't be processed in high temperature furnaces or by annealing procedures. Further, because the wafer substrate is just pasted on the carrier, it is easy to cause the wafer substrate break at high temperature.

Considering above situations, the inventor of the present invention tries to provide a method for forming the interposer without using the wafer substrate to solve the above issues.

### SUMMARY OF THE INVENTION

The present invention provides a method for forming a waferless interposer. First, a transparent carrier is provided. A buffer layer is then formed on the transparent carrier. A plurality of first pads are formed on the buffer layer. A plurality of interconnections are formed on the first pads. A non-conductive layer is formed on the buffer layer and filled between adjacent the interconnections. The upper surfaces of the interconnections are exposed on the non-conductive layer. A first redistribution procedure is performed to form a first conductive pattern on the non-conductive layer for connecting with the interconnections. A passivation layer is formed on the first conductive pattern. A plurality of first contact holes are formed on the passivation layer. A plurality of second pads are formed on the passivation layer to connect with the first conductive pattern through the first contact holes. Then, a laser below the transparent carrier irradiates laser beam on the buffer layer to dissociate it for separating the manufactured interposer from the transparent carrier.

In an embodiment, the transparent carrier is made of quartz glass, borosilicate glass, sodium silicate glass or sapphire glass.

In an embodiment, the buffer layer is made of ceramic optical material, metal material or nonmetal material. More specifically, the ceramic optical material such as gallium nitride (GaN), aluminum nitride (AlN), aluminum oxide (AlO) or zinc oxide (ZnO) can be chosen to form the buffer layer. The nonmetal material such as silicon nitride (SixNx), silicon oxide (SixOx), silicon (Si) or silicon carbide (SiC) can be chosen to form the buffer layer. The metal material such as titanium (Ti), titanium tungsten (TiW), nickel (Ni), aluminum (Al), copper (Cu), gold (Au) or silver (Ag) can be chosen to form the buffer layer.

In an embodiment, the step of forming the non-conductive layer further includes the steps of depositing a silicon layer on the buffer layer, the first pads and the interconnections, and then polishing the silicon layer until the upper surfaces of the interconnections being exposed. In another embodiment, the step of forming the non-conductive layer further includes the steps of coating a glass layer on the buffer layer and filled between adjacent the interconnections, wherein the upper surfaces of the interconnections are exposed on the glass layer. In a further embodiment, the step of forming the non-conductive layer further includes the steps of coating an organic layer on the buffer layer and filled between adjacent the interconnections, wherein the upper surfaces of the interconnections are exposed on the organic layer.

In an embodiment, the method further comprises of the following steps after performing the first redistribution procedure to form the first conductive pattern. A first dielectric layer is formed on the non-conductive layer to cover the non-conductive layer and the first conductive pattern. Then, the contact holes are formed on the first dielectric layer to expose parts of the first conductive pattern. Next, a second redistribution procedure is performed to form a second conductive pattern on an upper surface of the first dielectric layer, wherein the second conductive pattern connects to the first conductive pattern through the contact holes.

In an embodiment, the above redistribution procedure can be performed repeatedly to fabricate required number of redistribution layers on the interconnections and the non-conductive layer.

### BRIEF DESCRIPTION OF THE DRAWINGS

FIG. 1 illustrates the steps of forming a waferless interposer according to the present invention; and

FIG. 2A to FIG. 2G illustrate the cross-sectional views of the waferless interposer in each phase of the process according to the present invention.

### DESCRIPTION OF THE PREFERRED EMBODIMENT

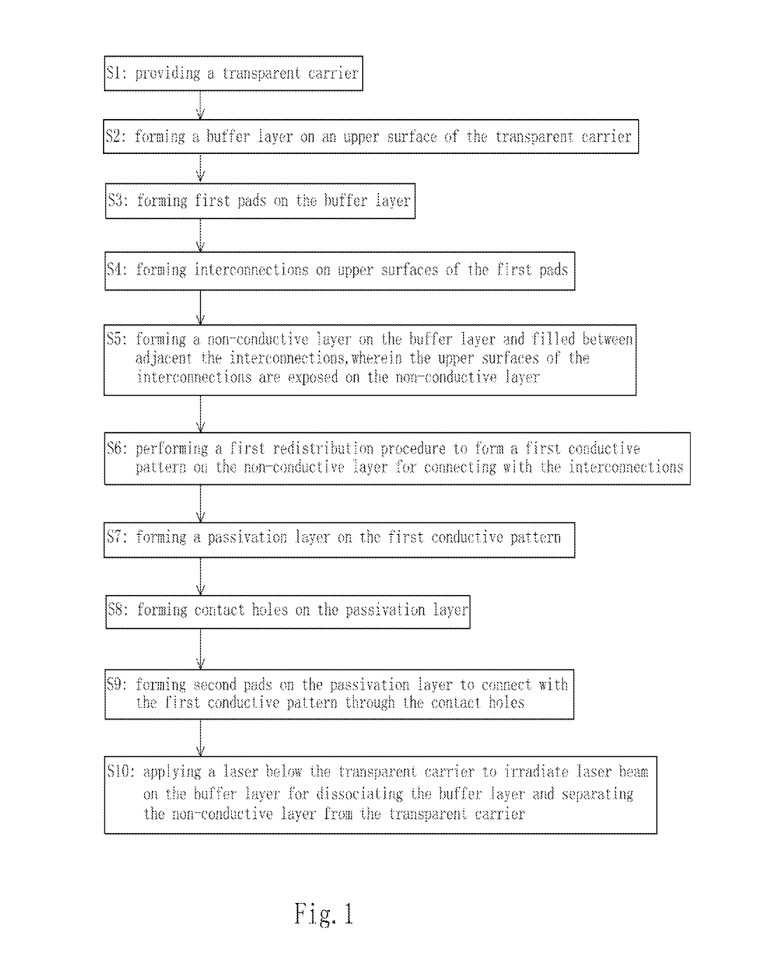

Please refer to FIG. 1, the steps of forming a waferless interposer are shown. The step S1 is providing a transparent carrier. Then, the step S2 is forming a buffer layer on an upper surface of the transparent carrier. The step S3 is forming first pads on the buffer layer. The step S4 is forming interconnections on upper surfaces of the first pads. Next, the step S5 is forming a non-conductive layer on the buffer layer and filled between adjacent the interconnections, wherein the upper surfaces of the interconnections are exposed on the non-conductive layer. The step S6 is performing a first redistribution procedure to form a first conductive pattern on the non-conductive layer for connecting with the interconnections. The step S7 is forming a passivation layer on the first conductive pattern. The step S8 is forming contact holes on the passivation layer. Then, the step S9 is forming second pads on the passivation layer to connect with the first conductive pattern through the contact holes. After, the step S10 is applying a laser below the transparent carrier to irradiate laser beam on the buffer layer for dissociating the buffer layer and separating the non-conductive layer from the transparent carrier.

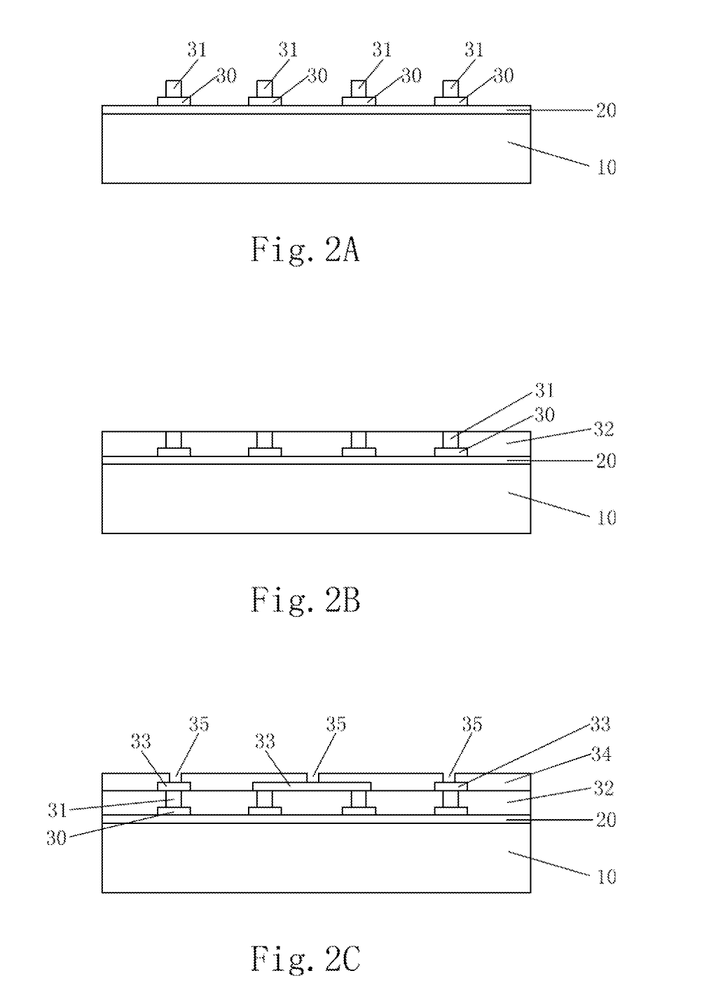

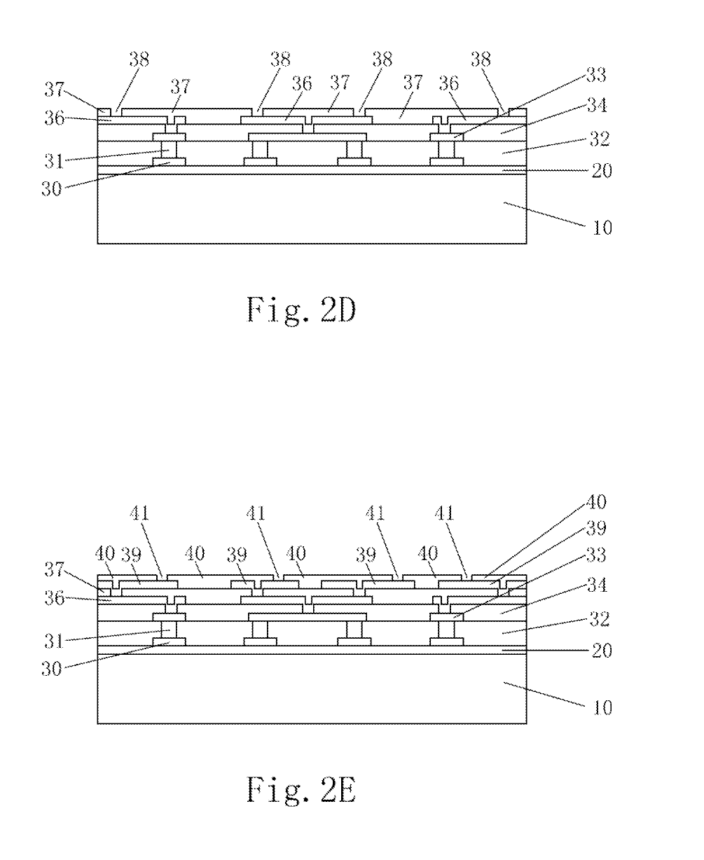

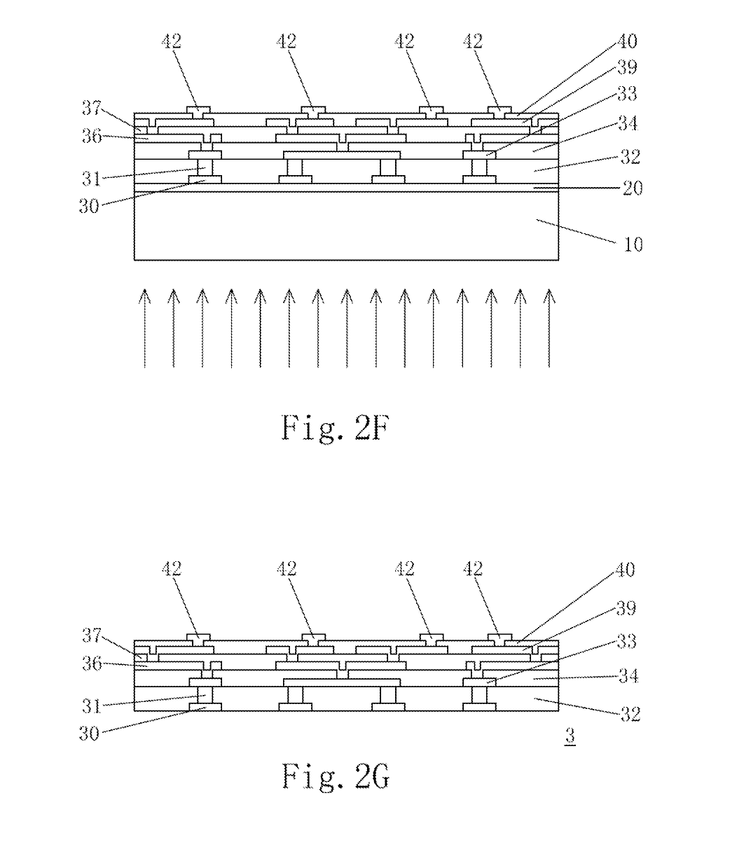

Please refer to FIG. 2A to FIG. 2G, these drawings illustrate the cross-sectional views of the waferless interposer in each phase of the process according to the present invention.

As shown in FIG. 2A, a transparent carrier 10 is provided. In a preferred embodiment, the transparent carrier 10 is made of quartz glass, borosilicate glass, sodium silicate glass, sapphire glass or any combinations thereof. Then, a buffer layer 20 is formed on an upper surface of the transparent carrier 10. The material of the buffer layer 20 can be ceramic optical material, metal material or nonmetal material. More specifically, in an embodiment, the ceramic optical material such as gallium nitride (GaN), aluminum nitride (AlN), aluminum oxide (AlO), zinc oxide (ZnO) or any combinations thereof can be chosen to form the buffer layer 20. In another embodiment, the nonmetal material such as silicon nitride (SixNx), silicon oxide (SixOx), silicon (Si), silicon carbide (SiC) or any combinations thereof can be chosen to form the buffer layer 20. In a further embodiment, the metal material such as titanium (Ti), titanium tungsten (TiW), nickel (Ni), aluminum (Al), copper (Cu), gold (Au), silver (Ag) or any combinations thereof can be chosen to form the buffer layer 20. Next, a plurality of first pads 30 are formed on an upper surface of the buffer layer 20, and a plurality of interconnections 31 are formed on upper surfaces of the first pads 30. These first pads 30 could be connected electrically with the printed circuit boards in later packaging procedure by means of solder balls. The interconnections 31 with pillar structures are formed directly on the first pads 30 to serve as through glass vias (TGV), through silicon vias (TSV), through organic vias (TOV) or through ceramic vias (TCV).

Please refer to FIG. 2B, a non-conductive layer 32 is then formed on the buffer layer 20 and filled between adjacent the interconnections 31 and between adjacent the first pads 30. Because the non-conductive layer 32 does not cover the interconnections 32, the upper surfaces of the interconnections 31 are exposed on the non-conductive layer 32.

It is noted that the non-conductive layer 32 can be formed of different material and by different processes to meet the requirements of manufacturers. For instance, the non-conductive layer 32 can be formed of dielectric material, insulating material or semiconductor material. In an embodiment, when the non-conductive layer 32 is formed of silicon, the step of forming the non-conductive layer 32 further includes the steps of depositing a silicon layer on the buffer layer 20, the first pads 30 and the interconnections 31, and then polishing the silicon layer until the upper surfaces of the interconnections 31 being exposed. In this embodiment, the interconnections 31 penetrating through the silicon layer are served as the through silicon vias (TSV).

In another embodiment, when the non-conductive layer 32 is formed of glass, the step of forming the non-conductive layer 32 further includes the steps of coating a glass layer on the buffer layer 20 and filled between adjacent the interconnections 31 and adjacent the first pads 30. The upper surfaces of the interconnections 31 are exposed on the glass layer. In this embodiment, the interconnections 31 penetrating through the glass layer are served as the through glass vias (TGV).

In an embodiment, when the non-conductive layer 32 is formed of organic material, the step of forming the non-conductive layer 32 further includes the steps of coating an organic layer on the buffer layer 20 and filled between adjacent the interconnections 31 and adjacent the first pads 30. The upper surfaces of the interconnections 31 are exposed on the organic layer. In this embodiment, the interconnections 31 penetrating through the organic layer are served as the through organic vias (TOV).

Please refer to FIG. 2C, a first redistribution procedure is then performed to form a first conductive pattern 33 on the non-conductive layer 32 for connecting with the interconnections 31. Next, a first dielectric layer 34 is formed on the non-conductive layer 32 to cover the non-conductive layer 32 and the first conductive pattern 33. Then, the first dielectric layer 34 is defined to form a plurality of contact holes 35 thereon for exposing parts of the first conductive pattern 33.

Please refer to FIG. 2D, after the first dielectric layer 34 is formed, a second redistribution procedure is performed to form a second conductive pattern 36 on an upper surface of the first dielectric layer 34 to connect the first conductive pattern 33 through the contact holes 35. Then, a second dielectric layer 37 is formed on the second conductive pattern 36, and the second dielectric layer 37 is defined to form a plurality of contact holes 38 thereon for exposing parts of the second conductive pattern 36.

It is noted that the number of times of the redistribution procedure can be adjusted by requirements. More redistribution layers (RDL) can be applied to meet the different packaging requirements. Please refer to FIG. 2E, in this embodiment, three redistribution layers are formed. Therefore, after the second dielectric layer 37 is formed, a third redistribution procedure is performed to form a third conductive pattern 39 on the second dielectric layer 37 to connect with the second conductive pattern 36 through the contact holes 38. Then, a passivation layer 40 is formed on the third conductive pattern 39, and a plurality of contact holes 41 are formed on the passivation layer 40 to expose parts of the third conductive pattern 39.

Please refer to FIG. 2F, a plurality of second pads 42 are formed on the passivation layer 40 to connect with the third conductive pattern 39 through the contact holes 41. The second pads 42 can be electrically connected with the pins of a chip in later packaging procedure. After the second pads 42 are formed, a laser is applied to irradiate a laser beam on the buffer layer 20 from the lower surface of the transparent carrier 10, as the arrows shown in FIG. 2F, to dissociate the buffer layer 20 for separating the first pads 30 and the non-conductive layer 32 from the transparent carrier 10. Namely, by using the laser the fabricated interposer 3, as shown in FIG. 2G, can be separated from the transparent carrier 10. In an embodiment, a laser such as a deep ultraviolet laser (DUV laser), an ultraviolet laser (UV laser), a visible light laser or an infrared laser (IR Laser) can be chosen for dissociating the buffer layer 20. Because the transparent carrier 10 is transparent to light, the laser beam can go through the transparent carrier 10 and irradiate on the buffer layer 20 for dissociating the buffer layer 20.

It is noted that the laser for dissociating the buffer layer 20 would be changed with different material of the transparent carrier 10. For instance, when the transparent carrier 10 is formed of quartz glass or sapphire glass, the laser could be a deep ultraviolet laser, an ultraviolet laser, a visible light laser or an infrared laser. When the transparent carrier 10 is formed of borosilicate glass or sodium silicate glass, the laser could be an ultraviolet laser, a visible light laser or an infrared laser. When the transparent carrier 10 is formed of silicon substrate or silicon carbide substrate, the laser could be an infrared laser.

Besides, the laser would be changed with different material of the buffer layer 20 for promoting the dissociating effect. For instance, when the buffer layer is formed of the ceramic optical material such as gallium nitride (GaN), aluminum nitride (AlN), aluminum oxide (AlO) or zinc oxide (ZnO), the laser could be the deep ultraviolet laser. When the buffer layer is formed of the metal material such as titanium (Ti), titanium tungsten (TiW), nickel (Ni), aluminum (Al), copper (Cu), gold (Au) or silver (Ag), the laser could be the deep ultraviolet laser or the ultraviolet laser. When the buffer layer 20 is formed of the nonmetal material such as silicon (Si), silicon carbide (SiC), silicon nitride (SixNx) or silicon oxide (SixOx), the laser could be the deep ultraviolet laser or the ultraviolet laser.

In a preferred embodiment, the transparent carrier 10 is formed of quartz glass or sapphire glass. Compared with borosilicate glass and sodium silicate glass, the quartz glass or sapphire glass has high hardness, high transmittance, high heat resistance and high acid and alkali resistance, and therefore can be processed at high temperature.

In a preferred embodiment, the transparent carrier 10 is formed of quartz glass. Compared with borosilicate glass and sodium silicate glass, the quartz glass has high transmittance. The laser beam with wavelength less than 300 nanometers can still go through the quartz glass and irradiate on the buffer layer 20 for dissociating the buffer layer 20. Especially, when the buffer layer 20 is formed of aluminum nitride, it is required to apply a deep ultraviolet layer with wavelength about 266 nanometers for effectively dissociating the buffer layer 20 due to the transmittance of aluminum nitride. Therefore, the quartz glass is chosen to form the transparent carrier 10.

In a preferred embodiment, the buffer layer 20 is made of titanium. Compared with aluminum nitride, the titanium film is easier to fabricate and can be dissociated by the ultraviolet laser with wavelength about 365 nanometers. Because the power required to dissociate the titanium film is very small, using the buffer layer 20 made of titanium can reduce the process time and heat effect.

Please refer to FIG. 2G, the cross-sectional view of the interposer 3 fabricated according to the present invention is shown. As aforementioned, the first pads 30 beneath the interposer 3 and the second pads 42 on the interposer 3 are individually applied in later packaging procedure to connect with the printed circuit boards and chips. Through the interconnections 31, the first conductive pattern 33, the second conductive pattern 36 and the third conductive pattern 39 formed in the interposer 3, the chips can connected electrically with the printed circuit boards.

The method of forming the waferless interposer provided by the present invention has various advantages.

First, compared with the method of thinning the wafer substrate by chemical mechanical polishing (CMP) in prior art, the method provided by the present invention relieves the polishing procedure used for thinning wafer, thereby saving process time and increasing production rate of the interposer.

Second, the waferless interposer of the present invention is directly fabricated on the transparent carrier, which means that the method of the present invention can be applied to fabricate ultra thin interposers with less stress to meet the requirements of manufacturers.

Further, compared with the step of polishing the wafer substrate to remove a considerable amount of wafer in the prior art, it is obvious that the method of the present invention is more friendly to environment and can reduce costs of materials. Especially, because the transparent carriers can be used repeatedly, the production costs can be further reduced.

The preferred embodiments of the invention have been set forth as above description, however the spirit and scope of the present invention are not limited to the aforementioned embodiments. Therefore, the appended claims are intended to cover all embodiments which do not depart from the spirit and scope of the invention.

What is claimed is:

1. A method of forming a waferless interposer comprising the steps of:
providing a transparent carrier;
forming a buffer layer on an upper surface of the transparent carrier;
forming a plurality of first pads on the buffer layer;
forming a plurality of interconnections on the first pads;
forming a non-conductive layer on the buffer layer and filled between adjacent the interconnections, wherein upper surfaces of the interconnections are exposed on the non-conductive layer;
performing a first redistribution procedure to form a first conductive pattern on the non-conductive layer for connecting with the interconnections;
forming a passivation layer on the first conductive pattern;
forming a plurality of first contact holes on the passivation layer;
forming a plurality of second pads on the passivation layer to connect with the first conductive pattern through the first contact holes; and
applying a laser below the transparent carrier to irradiate laser beam on the buffer layer for dissociating the buffer layer and separating the first pads and the non-conductive layer from the transparent carrier.

2. The method of forming a waferless interposer of claim 1, wherein the transparent carrier is made of quartz glass, borosilicate glass, sodium silicate glass, sapphire glass or any combinations thereof.

3. The method of forming a waferless interposer of claim 1, wherein the buffer layer is made of gallium nitride (GaN), aluminum nitride (AlN), aluminum oxide (AlO), zinc oxide (ZnO) or any combinations thereof.

4. The method of forming a waferless interposer of claim 1, wherein the step of forming the non-conductive layer further includes the steps of:
depositing a silicon layer on the buffer layer, the first pads and the interconnections; and
polishing the silicon layer until the upper surfaces of the interconnections being exposed.

5. The method of forming a waferless interposer of claim 1, wherein the step of forming the non-conductive layer further includes the steps of:
coating a glass layer on an upper surface of the buffer layer and filled between adjacent the interconnections, wherein the upper surfaces of the interconnections are exposed on the glass layer.

6. The method of forming a waferless interposer of claim 1, wherein the step of forming the non-conductive layer further includes the steps of:
coating an organic layer on an upper surface of the buffer layer and filled between adjacent the interconnections, wherein the upper surfaces of the interconnections are exposed on the organic layer.

7. The method of forming a waferless interposer of claim 1, after performing the first redistribution procedure to form the first conductive pattern, further including of the steps of:
forming a first dielectric layer on the non-conductive layer to cover the non-conductive layer and the first conductive pattern;
forming a plurality of second contact holes on the first dielectric layer to expose parts of the first conductive pattern; and
performing a second redistribution procedure to form a second conductive pattern on an upper surface of the first dielectric layer, wherein the second conductive pattern connects to the first conductive pattern through the second contact holes.

8. The method of forming a waferless interposer of claim 7, after performing the second redistribution procedure to form the second conductive pattern, further including of the steps of:
forming a second dielectric layer on the second conductive pattern and the first dielectric layer;
forming a plurality of third contact holes on the second dielectric layer to expose parts of the second conductive pattern; and
performing a third redistribution procedure to form a third conductive pattern on an upper surface of the second dielectric layer, wherein the third conductive pattern connects to the second conductive pattern through the third contact holes.

9. The method of forming a waferless interposer of claim 1, wherein the buffer layer is made of silicon (Si), silicon carbide (SiC), silicon nitride (SixNx), silicon oxide (SixOx), or any combinations thereof.

10. The method of forming a waferless interposer of claim 1, wherein the buffer layer is made of titanium (Ti), titanium tungsten (TiW), nickel (Ni), aluminum (Al), copper (Cu), gold (Au), silver (Ag) or any combinations thereof.
